(19) United States
(12) Patent Application Publication
(10) Pub. No.: US 2025/0271489 A1
(43) Pub. Date: Aug. 28, 2025

(54) THERMAL SHOCK TESTING APPARATUS AND THERMAL SHOCK TESTING METHOD

(71) Applicant: Mitsubishi Electric Corporation, Tokyo (JP)

(72) Inventor: Koji YAMAZAKI, Tokyo (JP)

(73) Assignee: Mitsubishi Electric Corporation, Tokyo (JP)

(21) Appl. No.: 18/857,574

(22) PCT Filed: Apr. 27, 2022
(86) PCT No.: PCT/JP2022/019075

§ 371 Date: Oct. 17, 2024

(51) Int. Cl. G01R 31/26

(52) U.S. Cl. CPC G01R 31/2642

(57) ABSTRACT

A thermal shock testing apparatus includes a test chamber in which a test sample is placed, and which is sealed; a chiller which cools the test chamber to a predetermined temperature with coolant; a lamp heater which heats the test sample to a target temperature; a temperature sensor which detects a temperature of the test sample; a control device which controls the operation of the chiller, and the energization and shut-off of the lamp heater. The test sample is heated to a target temperature with the lamp heater, after the test chamber is cooled to a predetermined temperature. Thereafter, the energization of the lamp heater is shut off, and a thermal shock is added to the test sample. Thereby, a thermal shock test can be conducted in a short time.

### TECHNICAL FIELD

The present disclosure relates to a thermal shock testing apparatus and a thermal shock testing method.

### BACKGROUND ART

In recent years, development for applying semiconductor devices whose base material is silicon carbide (Sic) or gallium nitride (GaN) to power modules has been actively conducted as the next generation devices, from the viewpoint of energy saving. The semiconductor device used in the power module has an operation temperature which is set at 175° C. or higher, from the viewpoint of reducing the power loss. Moreover, the operation temperature is expected to reach 300° C. in the future, and high reliability is required in the power module. Moreover, a long service life will be demanded, when the power module needs to achieve both high operation temperature and high reliability. Accordingly, a problem will arise in that an evaluation period may be also extended.

Furthermore, in these days, semiconductor devices have been used in a wide variety of applications, and their test conditions cover a wide range. For example, there is also a user specific testing method called a combined cycle test in which a low temperature holding test is conducted after a thermal shock test is performed, and further, a power cycle test is added in which the semiconductor device is thereafter operated and energized for heating. If a new testing method is required in this way, the period for evaluating the reliability will be further prolonged, and this will cause the lengthening of the development period of new power modules.

On the other hand, in the environmental testing apparatus of Patent Document 1, an environmental testing apparatus is disclosed in which a rotating heat insulation wall is provided, a test sample is stored in a test chamber, a low temperature constant humidity part is equipped with a low temperature adjustment device, and a high temperature constant humidity part is equipped with a high temperature adjustment device. Those adjustment devices are both heat source machines, and the rotating heat insulation wall divides the test chamber into the low temperature constant humidity part and the high temperature constant humidity part. The environmental testing apparatus includes a fulcrum and an electric motor with which this rotating heat insulation wall can be rotated at least 180 degrees, with the center of the test chamber as the fulcrum. Moreover, since the test sample can be mounted on the rotating heat insulation wall, space is secured in the test chamber. In a suitable space domain inside the test chamber, a local heating device such as a far infrared lamp or a local cooling device such as a spot type chiller is prepared, for example. In the apparatus, local heating or cooling can be further conducted, while carrying out a temperature-humidity test to the test sample.

### CITATION LIST

### Patent Document

Patent Document 1: JP-H05-215658A

### SUMMARY OF THE INVENTION

### Problem to be Solved by the Invention

According to the environmental testing apparatus of the Patent Document 1, the temperature inside the environmental test chamber is adjusted by a local heating device such as a far infrared lamp, or a local cooling device such as a spot type chiller, provided in the apparatus. Since the inside of the chamber is, however, not held at a low temperature or high temperature in advance, there arises a problem in that heating or cooling in a short time is difficult to attain.

The present disclosure is made in order to solve the problem mentioned above, and it aims at achieving a thermal shock testing apparatus which is capable of performing the thermal shock test of a test sample in a short time and also at high speed.

### MEANS TO SOLVE THE PROBLEM

A thermal shock testing apparatus, which is disclosed in the present disclosure includes:
a test chamber in which a test sample is placed, and which is sealed,
a chiller which circulates coolant inside the test chamber, and cools inside of the test chamber,
a heater which is installed inside of the test chamber, and heats the test sample,
a temperature sensor which detects a temperature of the test sample, and
a control device which controls the operation of the chiller, and the energization and shut-off to the heater, based on a temperature,
   wherein the heater is energized, after the inside of the test chamber is cooled to a predetermined temperature by the chiller, and
the energization to the heater is shut off and the test sample is cooled, after the test sample is heated to a target temperature.

A thermal shock testing method, which is disclosed in the present disclosure includes:
a process of placing a test sample inside a test chamber, and sealing the test chamber,
a process of circulating coolant of a chiller into the test chamber, and cooling the inside of the test chamber to a predetermined temperature,
a process of energizing a heater installed inside of the test chamber, and heating the test sample to a target temperature, and
a process of shutting off the energization to the heater, and cooling the test sample.

### Advantages Effects of the Invention

According to the thermal shock testing apparatus of the present disclosure, a test sample is heated in the state where the test chamber is cooled at a predetermined temperature with the chiller, by using a heater which is capable of heating locally at an increased heat up rate, from under a low temperature environment. Thereby, a thermal shock can be added to a test sample, and a reliable thermal shock evaluation test can be conducted in a short time and also at high speed, and then, it becomes possible to effectively attain the shortening of the evaluation time.

### BRIEF DESCRIPTION OF DRAWINGS

FIG. 1 is a schematic drawing for showing the overall structure of a thermal shock testing apparatus according to the Embodiment 1.

FIG. 2 is a drawing for showing the example of the temperature distribution on the pipe surface of a lamp heater used in the thermal shock testing apparatus the Embodiment 1.

FIG. 3 is a drawing for showing the flow chart of the thermal shock testing method according to the Embodiment 2.

### DESCRIPTION OF EMBODIMENTS

### Embodiment 1

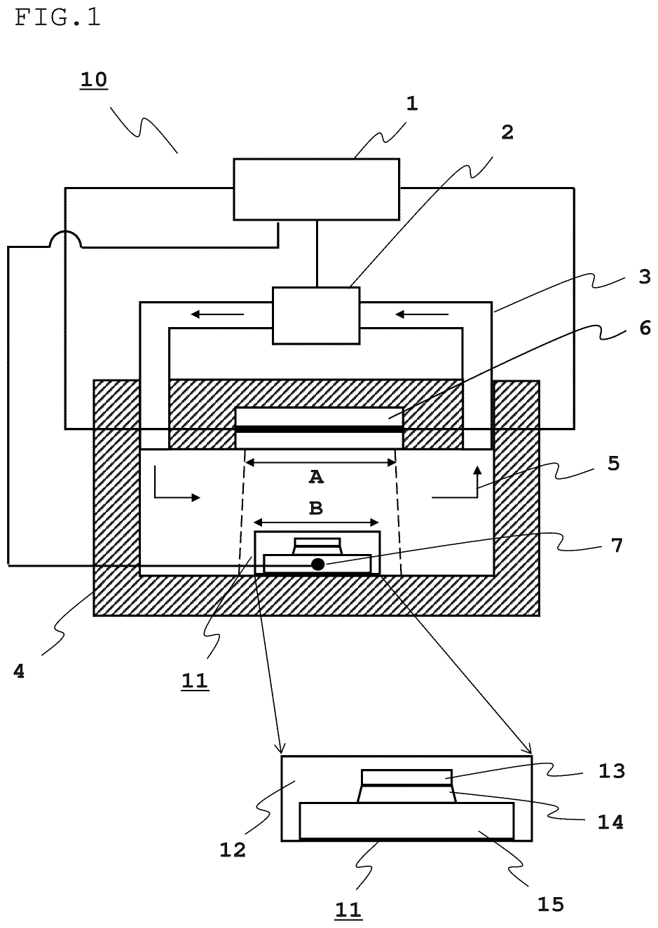

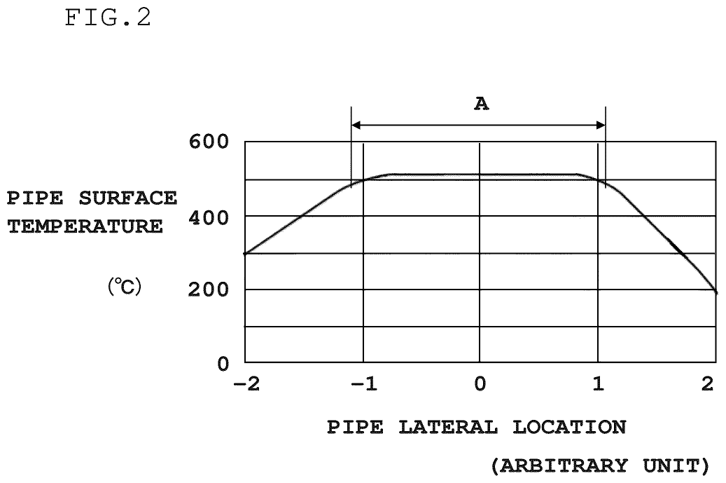

FIG. 1 is a schematic drawing for showing the overall structure of a thermal shock testing apparatus according to the Embodiment 1. FIG. 2 is a drawing for showing the example of the temperature distribution on the pipe surface of a lamp heater used in the thermal shock testing apparatus according to the Embodiment 1.

First, with reference to FIG. 1, explanation will be made about the overall structure of a thermal shock testing apparatus 10 according to the Embodiment 1. The thermal shock testing apparatus 10 is composed of a test chamber 4 inside of which a test sample 11 is placed, and which is sealed; a chiller 2 which cools the inside of the test chamber 4 to a predetermined temperature, by the circulation of coolant 5 through a coolant pipe 3; a lamp heater 6 which is installed in the test chamber 4 to face the test sample 11, and heats the test sample 11; a temperature sensor 7 which detects the temperature of the test sample 11, and a control device 1 which controls the operation of the chiller 2 and the energization and shut-off to the lamp heater 6, according to the temperature of the test sample 11.

The thermal shock test is one of the environmental tests which check how resistant an electronic component or apparatus is to changes in ambient temperature. This shock test is the one to evaluate the resistance to temperature changes in a short time, by repeatedly applying the temperature difference of high and low temperatures. Power semiconductor elements need to have the resistance to high temperature stress against large currents, and thereby, the test is required to be conducted in the range of 250° C. to 300° C. at a high temperature side to be targeted, and is required to be conducted in the range of −70° C. to 0° C. at a low temperature side to be held. The target temperature at the high temperature side and the predetermined temperature to be held at the low temperature side are, in fact, determined according to the demand of the evaluation test of a test sample.

High speed switching from a low temperature to a high temperature, and also from a high temperature to a low temperature is required in the thermal shock test. According to the present disclosure, in the exposure test of the test sample 11, switching between the high temperature side and the low temperature side is quickly performed by the combination of the chiller 2 which cools the test chamber 4 and the lamp heater 6 which heats the test sample 11.

In the present Embodiment, as shown in FIG. 1, a semiconductor module in which the semiconductor device 13 is mounted on the lead frame 15 via the jointing material 14 is provided as an example of the test sample 11. Here, the portion mounted with the semiconductor device 13 is further sealed with the mold resin 12. This test sample 11 may be formed of any constitutional material, and there is no particular restriction on the constitutional material. In general, aluminum or shiny material is, however, difficult to absorb the heat of the lamp heater 6, and takes time to be heated. This material will be heated as a whole by heating other portions, and then, heating can be conducted without a problem. For example, applying carbon spray to the surface of shiny aluminum enhances the heat absorption, and enables the heating of the sample. Any surface modification may be performed on the test sample 11.

In the test chamber 4, the test sample 11 is placed. The test chamber 4, kept in the sealed state 4, is held in the cooled state at a predetermined temperature (here, low temperature from less than 0°° C. to minus 10° C., or so) with the coolant 5 which is circulated through the coolant pipe 3 by the chiller 2. In general, when the test sample 11 is took in and out from the test chamber 4, the inside of the test chamber 4 is exhausted with a pump (not shown), or is returned to an atmospheric pressure. As the coolant (circulation liquid) 5, fluorine-based coolant in the first place, alcohol-based coolant, or their mixed solution, can be selected and used according to a target cooling temperature. The material of the coolant 5 can be decided so that the problem of corrosion or ice coating may not arise, taking the material used for the inner wall of the test chamber 4 and the test sample 11, into consideration.

For example, the inner wall surface of the test chamber 4 may be applied with the coating agent which suppresses ice coating. Or, it is allowed to perform the water repellent coating which prevents the adhesion of moisture, and surface modification for having a surface structure which enables water repellency. Moreover, covering the outer periphery of the test chamber 4 with heat insulating material such as glass wool makes it possible to efficiently cool the inside of the test chamber 4 and hold the inside at a constant temperature. Moreover, the test chamber 4 is allowed to have a vacuum insulating structure.

As a heater for heating the test sample 11, the lamp heater 6 is installed at a position to face the test sample 11, and inside the test chamber 4 which the test sample 11 is placed in.

With regard to the lamp heater 6, the heater is referred to as a lamp heater here, in the case where a halogen lamp is used as a heater. When filament whose main component is tungsten, for example, is energized to have a high temperature, light will be emitted from the filament. The halogen lamp uses the emitted light (the wavelength of those electromagnetic waves ranges from near infrared region to visible region.). The efficiency of converting to visible light is very low, as low as 10% or less, but the efficiency of converting to all electromagnetic waves, including light of the infrared region, is around 90%. The halogen lamp is very efficient heating means. The temperature of the filament will reach about 2500°° C. to 3000°° C., and the halogen lamp can attain also non-contact and clean heating of 1300°° C. to 1500° C., when the light is collected.

However, only a part of the test sample 11 can be heated, when focused light is used. So, in the present disclosure, a lamp heater called parallel light type is used, which is capable of attaining uniform heating within a certain range. This comes from the fact that a test such as at several thousand ° C., for example, will not be conducted in the actual thermal shock test for semiconductor devices (fracture will be caused by the dissolution of in-mold resin, or dissolution of jointing material.). Therefore, focusing of light is not necessary, and then, a lamp heater of parallel light type is adopted.

FIG. 2 shows an example of the temperature distribution on the pipe surface of the lamp heater 6. Here, 95% of the peak temperature is referred to as a uniform heat length A. The size B of the test sample 11 is preferably within 80%, with respect to the uniform heat length A, which is relevant to the peak temperature on the pipe surface in the longitudinal direction of the lamp heater 6. Thereby, the shock testing apparatus can apply uniform heat load to the test sample 11.

The temperature sensor 7 is the one to detect the temperature of the test sample 11, and, in FIG. 1, a thermocouple is attached to the lead frame 15 on which the semiconductor device 13 is mounted. The temperature sensor 7 detects the temperature of the test sample 11, and sends a signal to a control device 1 mentioned later. Here, explanation will be made about a case in which a thermocouple is used as the temperature sensor 7. A window can be provided on the wall of the test chamber 4, and the temperature sensor 7 may be the one to optically detect the temperature of the test sample 11 in a non-contact manner.

The control device 1 is the one to control the operation of the chiller 2 which cools the test chamber 4. And the control device 1 judges that the temperature of the test sample 11, which is detected with the temperature sensor 7, has become a predetermined low temperature and a target high temperature, and is the one to control the execution of the energization and shut-off to the lamp heater 6. The test sample 11 is attached with a thermocouple as the temperature sensor 7, and this thermocouple is connected to the control device 1. Based on the temperature detected with the thermocouple, the control device 1 executes the operation of the chiller 2, and the energization and shut-off of the lamp heater 6. Moreover, adjusting the output of the lamp heater 6 makes it possible to control the heat up rate of the sample.

Description will be given further about the problem of accretion of ice on the surface of the lamp heater 6. For example, ice adheres on the surface of the lamp heater 6 by cooling the test chamber 4, and emitted light from the lamp heater 6 is not normally absorbed by the test sample 11. To prevent the non-normal absorption, it is also effective to operate at all times the lamp heater 6 at a low output, so that the accretion of ice may not be formed at least on the surface of the lamp heater 6. Or, water repellent coating agent and the like, which can suppress the accretion of ice, may be applied on the surface of the lamp heater 6, and this makes it possible to deal with the problem. The above agent deals with the case in which the coolant 5 contains moisture. For example, it is enough to form the test chamber 4 at least into sealed space, when fluorine-based coolant is dealt with. The sealed space, which is a structure to prevent the invasion of moisture, can suppress the accretion of ice. Moreover, alcohol-based coolant, such as ethanol, may also be used, according to the corresponding temperature. Moreover, two or more coolants may be mixed. As for the chiller 2, it is sufficient to select an adaptable chiller according to the temperature to be cooled. Moreover, regarding the cooling means, it is sufficient to keep the test chamber at a low temperature (minus temperatures), even if coolant is not directly flowed in. Channel may be provided on any one of the upper surfaces, wall surface, and bottom surface which constitute the test chamber. The coolant which flows into the channel can also hold the test chamber at a low temperature.

When a thermal shock test is conducted, the test sample 11 is at first placed in the test chamber 4, and the temperature sensor 7 is attached to the test sample 11 (In FIG. 1, the sensor is attached to the lead frame 15.). Then, after the test chamber 4 is sealed, the chamber is exhausted with a pump, and the coolant 5 of the chiller 2 is circulated in the test chamber 4 for cooling. After the control device 1 confirms, by the use of the temperature sensor 7, that the test sample 11 is cooled to a predetermined low temperature, the control device 1 starts the energization to the lamp heater 6, and the test sample 11 is heated to a target temperature. After the temperature of the test sample 11 is confirmed to have reached a target high temperature, the control device 1 shuts off the energization to the lamp heater 6. Then, the test sample 11 is cooled with the coolant 5 of the chiller 2. This temperature cycle will be repeated to carry out a thermal shock test.

It is to be noted that, in the present Embodiment, explained is the case in which a lamp heater is used as a heater capable of heating locally, but other heat sources may be used. Moreover, explained is the case in which heating is carried out in a state where the coolant is circulated, when a lamp heater is used to heat a test sample. However, the state in which circulation of the coolant is stopped temporarily may be allowed for carrying out heating. Moreover, here, a semiconductor module is mentioned as the example of a test sample, but this Embodiment can be applied to other test sample materials. The place where a test sample is placed in the test chamber is not limited to the bottom surface, but other places can be employed. In this case, the lamp heater needs to be arranged at the position to face a test sample.

In this way, according to the thermal shock testing apparatus according to the present Embodiment 1, the coolant of a chiller is circulated in the test chamber, and the test chamber is cooled to a predetermined temperature. In this state, a test sample is heated to a high temperature, by using the lamp heater which is capable of heating locally at an increased heat up rate, from under a low temperature environment. Thereby, a thermal shock can be added to a test sample, and a highly reliable thermal shock evaluation test can be conducted in a short time and also at high speed, and then, it becomes possible to effectively attain the shortening of the evaluation time.

### Embodiment 2

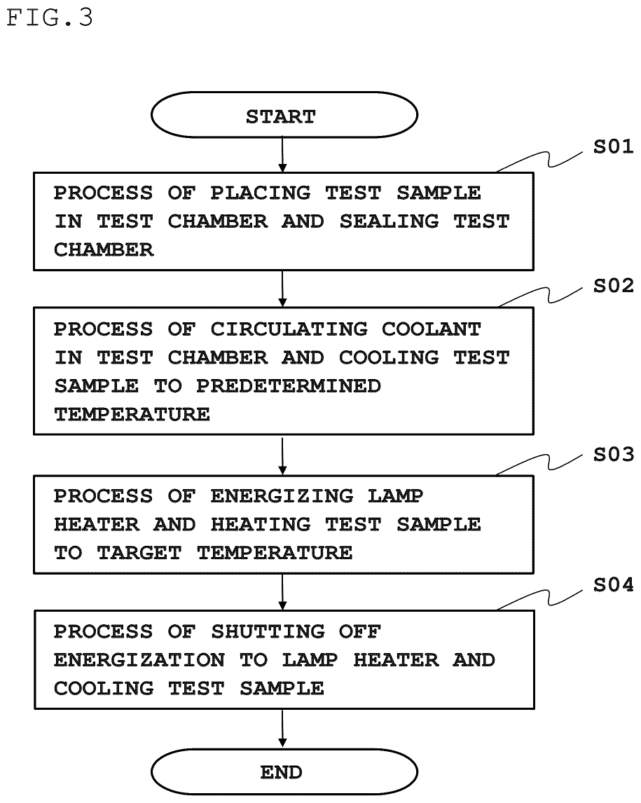

FIG. 3 is a drawing for showing the flow chart to explain a thermal shock testing method according to the Embodiment 2. Since the thermal shock testing apparatus 10 and its configuration are the same as those of the Embodiment 1, descriptions thereabout will be omitted.

With reference of FIG. 1, explanation will be made about the thermal shock testing method using the flow chart of FIG. 3. Here, a case will be exemplarily explained in which a thermal shock test for the test sample 11 is carried out between two temperatures of a low temperature and a high temperature.

First, in the process of Step S01, the test sample 11, which is attached with the temperature sensor 7, is placed in the test chamber 4. Thereafter, the inside of the test chamber 4 is sealed and the inside of the test chamber 4 is exhausted (not shown.).

Next, in the process of Step S02, the coolant 5 is circulated in the test chamber 4, and it is confirmed with the temperature sensor 7 that the test sample 11 has been cooled to a low temperature of a predetermined value.

Subsequently, in the process of Step S03, a predetermined low temperature is held for a predetermined time. Thereafter, the lamp heater 6 is energized, and it is confirmed with the temperature sensor 7 that the test sample 11 has been heated to a high temperature, which is set as a target temperature.

Furthermore, in the process of Step S04, the test sample 11 is held at a high temperature for a predetermined time. Thereafter, the energization to the lamp heater 6 is shut off, and the test sample 11 is cooled. Thereby, the processes for the thermal shock test are completed.

Depending on the contents of the intended thermal shock test, a thermal shock test will be carried out, by repeating the above-mentioned process of a low temperature and a high temperature, as many times as needed. Moreover, the test can be conducted also in other temperature patterns, if needed. It is to be noted that, in the series of processes described above, the control device 1 controls the chiller 2 and the lamp heater 6, based on the temperature detected with the temperature sensor 7.

In this way, according to the thermal shock testing method according to the Embodiment 2, the coolant of a chiller is circulated in a test chamber, and a test sample is cooled to a predetermined temperature. The test sample is heated locally at an increased heat up rate, with a lamp heater, from under a low temperature environment to a high temperature. Thereby, a thermal shock can be added to a test sample, and a highly reliable thermal shock evaluation test can be conducted in a short time and also at high speed, and then, it becomes possible to effectively attain the shortening of the evaluation time.

Although the present disclosure is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments.

It is therefore understood that numerous modifications which have not been exemplified can be devised without departing from the scope of the present disclosure. For example, at least one of the constituent members may be modified, added, or eliminated. At least one of the constituent members mentioned in at least one of the preferred embodiments may be selected and combined with the constituent members mentioned in another preferred embodiment.

### REFERENCE SIGNS LIST

1 Control Device, 2 Chiller, 3 Coolant Pipe, 4 Test Chamber, 5 Coolant, 6 Lamp Heater, 7 Temperature Sensor, 10 Thermal Shock Testing Apparatus, 11 Test Sample, 12 Mold Resin, 13 Semiconductor Device, 14 Jointing Material, 15 Lead Frame.

1. A thermal shock testing apparatus, comprising
a test chamber in which a test sample is placed, and which is sealed,
a chiller which circulates coolant inside the test chamber, and cools inside of the test chamber,
a heater which is installed inside of the test chamber, and heats the test sample,
a temperature sensor which detects a temperature of the test sample, and
a control device which controls the operation of the chiller, and the energization and shut-off to the heater, based on a temperature,
wherein the heater is energized, after the inside of the test chamber is cooled to a predetermined temperature by the chiller, and
the energization to the heater is shut off and the test sample is cooled, after the test sample is heated to a target temperature.

2. The thermal shock testing apparatus according to claim 1, wherein the heater is a lamp heater of parallel light type.

3. The thermal shock testing apparatus according to claim 2, wherein the lamp heater is installed to face the test sample, and the size of the test sample is within 80%, with respect to a uniform heat length of a peak temperature on a pipe surface of the lamp heater.

4. A thermal shock testing method, comprising
a process of placing a test sample inside a test chamber, and sealing the test chamber,
a process of circulating coolant of a chiller into the test chamber, and cooling the inside of the test chamber to a predetermined temperature,
a process of energizing a heater installed inside of the test chamber, and heating the test sample to a target temperature, and
a process of shutting off the energization to the heater, and cooling the test sample.

5. The thermal shock testing method according to claim 4, wherein the heater is a lamp heater of parallel light type.
